(19) United States
(12) Patent Application Publication
(10) Pub. No.: US 2026/0241445 A1
(43) Pub. Date: Aug. 20, 2026

(54) METHOD AND APPLICATION FOR VAN DER WAALS MISFIT LAYERED COMPOUNDS BASED ON SOLID-STATE HIGH-TEMPERATURE SYNTHESIS

(71) Applicant: University of Science and Technology of China, Hefei (CN)

(72) Inventors: Hui ZHANG, Hefei (CN); Haobo YANG, Hefei (CN); Cheng JIA, Hefei (CN); Wenyu HUANG, Hefei (CN)

(73) Assignee: University of Science and Technology of China, Hefei (CN)

(21) Appl. No.: 19/530,693

(22) Filed: Feb. 5, 2026

(30) Foreign Application Priority Data
Apr. 14, 2025 (CN) 202510459387.5

(51) Int. Cl. B22F 1/17; B22F 9/16

(52) U.S. Cl. CPC B22F 1/17; B22F 9/16

(57) ABSTRACT

The present disclosure provides a method and an application for vdW misfit layered compound based on solid-state high-temperature synthesis, and pertains to the field of functional device technology. The compound consists of at least two vdW material sublayers. In the preparation method, the structure existing under the condition of thermodynamic stability is synthesized by high-temperature sintering to achieve the alternating self-assembly growth of heterostructures. In terms of application, the functional device application regulation system is constructed to achieve the application of compounds in the fields of lateral ferroelectric metal memristors, vertical piezoelectric devices, and superconducting ferroelectric memristor devices. The present disclosure addresses the problems of complex process, low efficiency and high cost of conventional preparation of vdW misfit layered compounds, constructs the functional device application regulation system, achieves its wide application in various fields, and provides a novel direction for the future development of science and technology.

### TECHNICAL FIELD

The present disclosure relates to the field of functional device technology, particularly a method and an application for a van der Waals (vdW) misfit layered compound based on solid-state high-temperature synthesis.

### BACKGROUND

VdW materials and misfit layered compounds have attracted much attention in the field of materials research in recent years. The vdW materials are layered materials held together by vdW forces. Their unique layered structure endows them with many excellent characteristics, such as high flexibility and tunable electrical properties. Misfit layered compounds are composed of staggered two-dimensional (2D) components with different lattice constants, while misfit layered compounds based on 2D vdW materials exhibit weak interlayer vdW forces, allowing each component to retain its intrinsic properties. Therefore, they achieve the fusion of multiple characteristics and have a great potential for development in the field of functional devices in the future.

The emergence of 2D vdW layered ferroelectric materials has established a novel direction for the development of non-volatile devices with fully 2D material heterostructures in the future. Such material not only has the stable spontaneous polarization and strong nonlinear characteristics of conventional ferroelectric materials, but also has distinct advantages. These include a tunable band gap, which is of great significance in optoelectronic devices, and it can flexibly modulation the absorption and emission of light of different wavelengths. Additionally, these materials exhibit non-trivial quantum topological properties, providing novel material options for cutting-edge research in quantum computing and quantum communication. Consequently, novel vdW ferroelectrics are regarded as highly promising alternative materials for electronics and optoelectronics in the post-Moore era. They have demonstrated broad application prospects in multiple fields, including high-density integrated ferroelectric storage, neuromorphic computing, integrated optoelectronic sensing-storage-computing chips, nanogenerators, and photovoltaic devices.

Nevertheless, current research on vdW ferroelectric materials exhibits uneven development. While substantial progress has been made in studying the optical and electrical properties, where researchers have gained relatively deep insights into mechanisms such as optical absorption and emission as well as electrical conductivity characteristics, exploration of ferroelectricity remains largely unexplored. Many questions about the basic properties, ferroelectric phase transition mechanism and coupling relationship with other physical properties of vdW ferroelectric materials have not been adequately studied and explicitly resolved, which limits the optimization design and performance improvement of vdW ferroelectric materials in related devices to some extent.

In terms of the material preparation process, the preparation of conventional heterogeneous superlattice crystals mostly adopts a layer-by-layer preparation process. This process forms crystals by stacking materials layer by layer, which exposes many drawbacks in actual operation. Low deposition rate leads to low production efficiency, making it difficult to meet the requirements of large-scale industrial production. Poor scalability makes it difficult to prepare crystals with large sizes or complex structures. Poor stability, is easily interfered with by external environmental factors, resulting in uneven crystal quality. Moreover, the selection of materials is limited, and only specific matching materials can be selected for layer-by-layer stacking, which greatly limits the development and application potential of novel material systems, making it difficult to meet the growing demand for high-performance and multifunctional materials.

### SUMMARY

In order to overcome the limitations of the prior art, the present disclosure provides a method and an application for synthesizing vdW misfit layered compound based on solid state high temperature, which addresses the problems of complex process, low efficiency and high cost of conventional preparation of vdW misfit layered compounds, constructs a functional device application regulation system, achieves its wide application in various fields, and provides a novel direction for the future development of science and technology.

In order to achieve the above objective, the present disclosure provides the following solution:

a first objective of the present disclosure is to provide a vdW misfit layered compound based on solid-state high-temperature synthesis, the vdW misfit layered compound is prepared by a solid-state high-temperature synthesis method and consists of at least two vdW material sublayers, where a first layer of the vdW material sublayer is a compound layer containing group IV or group V transition metals, and a second layer of the vdW material sublayer is a compound layer containing tin, lead, bismuth, antimony or rare earth metal elements, and atoms of the two vdW material sublayers are connected by vdW force.

In some embodiments, a general chemical formula of the vdW misfit layered compound is ([MX]_{1+δ})ₘ(TX₂)ₙ; where M is defined as one element selected from the tin, lead, bismuth, antimony or rare earth metal elements, T is defined as a group IV or group V transition metal element, X is defined as a sulfur element or a selenium element, the parameter δ is defined as an in-plane area ratio of two components, m is a stoichiometric number of an MX layer, and n is a stoichiometric number of a TX₂ layer.

In some embodiments, the two vdW materials sublayers are a tetragonal phase layer A and a hexagonal phase layer B, respectively, and heterogeneous superlattices are formed based on stacking modes of ABAB and AAB; a crystal structure of the vdW misfit layered compound is characterized by a Raman spectroscopy and a scanning transmission electron microscopy-high-angle annular dark-field (STEM-HAADF), containing two distinct 2D components with different lattice constants, and exhibiting a staggered arrangement to form a misfit layered structure.

A second objective of the present disclosure is to provide a method for the vdW misfit layered compound based on the solid-state high-temperature synthesis, including the following steps:

according to a chemical formula of a target compound, weighing elemental powder of each element as a starting material, and obtaining mixed powder by uniformly mixing the above powder;

encapsulating the mixed powder and a transport agent together in a vacuum-sealed quartz tube;

placing the encapsulated quartz tube in a dual-temperature zone furnace, and setting temperatures of a source end of a precursor mixture and a crystallization end, and reacting and crystallizing the mixed powder in a vapor phase environment by using a chemical vapor transport method; and

after the reaction is finished, taking the quartz tube out from the dual-temperature zone furnace and quenching, cooling the crystal in the quartz tube from a reaction temperature to room temperature, fixing the crystal structure, and obtaining a vdW misfit layered compound single crystal, i.e., obtaining the vdW misfit layered compound.

In some embodiments, the transport agent is a stannous halide compound, and one of stannous chloride and stannous bromide is selected as the stannous halide compound.

In some embodiments, a temperature range of the source end of the precursor mixture source is 800-900 °C; the temperature range of the crystallization end is 750-850 °C, and the crystallization is performed by the chemical vapor transport method, with a growth time of 7-14 days.

A third objective of the present disclosure is to provide an application for the vdW misfit layered compound, the vdW misfit layered compound is applied in various functional devices based on its electrical properties, specifically including: a lateral ferroelectric metal memristor, a vertical piezoelectric device, and a superconducting ferroelectric memristor device.

In some embodiments, a hysteresis current-voltage hysteresis curve of an in-plane memristor of the vdW misfit layered compound has characteristics of low threshold voltage, and is further applied to the lateral ferroelectric metal memristor with low energy consumption.

In some embodiments, the crystal structure of the vdW misfit layered compound exhibits an out-of-plane symmetry breaking due to a mismatch between two groups of sublayer lattices, is deformed along a direction of an electric field under action of the electric field, and is applied to the vertical piezoelectric device with high-efficiency electromechanical conversion performance.

In some embodiments, the vdW misfit layered compound is an Ising superconductor, exhibits a high upper critical field, and further maintains a stable superconducting state under a strong magnetic field environment, and is applied to a superconducting ferroelectric memristive device with high stability.

According to the specific embodiments provided by the present disclosure, the following technical effects are disclosed:

(1) in the present disclosure, a method for the vdW misfit layered compound based on the solid-state high-temperature synthesis is provided, the mothed includes: by accurately controlling the stoichiometric ratio of each element, selecting an adapted transport agent, sintering and growing the compound in a high temperature region by means of a chemical vapor transport method, and stabilizing the structure and property of the compound by using a quenching process at a reaction temperature, thereby simplifying the conventional preparation process, overcoming the cumbersome layer-by-layer preparation process, improving the preparation efficiency and stability, and possessing higher industrial application potential, Accordingly, a large-scale production can be achieved at a lower cost, which lays a solid foundation for extensive studies and application of the compound.

(2) In the present disclosure, the provided vdW misfit layered compound exhibits a great potential for application in the field of functional devices, particularly in cutting-edge scientific and technological fields such as artificial intelligence. The compound can be used to construct non-volatile electronic devices, providing the possibility of achieving a brain-like architecture integrating storage and computing. Specifically, by developing devices including lateral ferroelectric metal memristors, vertical piezoelectric devices, superconducting ferroelectric memristor devices, etc., the demand for high-performance devices in brain-like computing and neural networks can be met, which promotes the development of artificial intelligence hardware, and provides a novel direction for future technological innovation.

### BRIEF DESCRIPTION OF THE DRAWINGS

To explain the embodiments of the present disclosure or the technical solutions in the prior art more clearly, a brief introduction will be made to the accompanying drawings used in the embodiments or the description of the prior art. It is obvious that the drawings in the description below are only some embodiments of the present disclosure, and those ordinarily skilled in the art can obtain other drawings according to these drawings without creative work.

FIG. 1 is a flow chart of a method for a vdW misfit layered compound based on solid-state high-temperature synthesis according to the present disclosure;

FIG. 2 is an X-ray diffraction (XRD) pattern of a (SnSe)_{1.16}(NbSe₂) crystal provided in Embodiment 1 according to the present disclosure;

FIG. 3 is an STEM-HAADF diagram of a (SnSe)_{1.16}(NbSe₂) crystal provided in Embodiment 1 according to the present disclosure;

FIG. 4 is a ferroelectric property diagram of a (SnSe)_{1.16}(NbSe₂) crystal obtained by a lateral piezoelectric force microscopy (LPFM) in Embodiment 1 according to the present disclosure; wherein FIG. 4(a) is a local electrically switching spectroscopy piezoresponse force microscopy (SS-PFM), FIG. 4(b) is an in-plane phase diagram of a square-loop pattern, and FIG. 4(c) is an amplitude domain diagram;

FIG. 5 is a piezoelectric effect diagram of a (SnSe)_{1.16}(NbSe₂) crystal obtained by vertical piezoelectric force microscopy (VPFM) in Embodiment 1 according to the present disclosure;

FIG. 6 is an electronic structure diagram of a (SnSe)_{1.16}(NbSe₂) crystal obtained by angle-resolved photoemission spectroscopy (ARPES) in Embodiment 1 according to the present disclosure; wherein FIG. 6(a) is a relationship between binding energy of the (SnSe)_{1.16}(NbSe₂) crystal and an in-plane wave vector k _{//} under excitation at 45 eV, FIG. 6(b) is a relationship between binding energy of the (SnSe)_{1.16}(NbSe₂) crystal and an in-plane wave vector k _{//} under excitation at 40 eV, FIG. 6(c) is a relationship between binding energy of the (SnSe)_{1.16}(NbSe₂) crystal and an in-plane wave vector k _{//} under excitation at 35 eV, and FIG. 6(d) is a relationship between binding energy of the crystal and an in- plane wave vector k _{//} under excitation at 30 eV;

FIG. 7 is a structural diagram of an in-plane memristor in Embodiment 4 according to the present disclosure; wherein FIG. 7(a) is a schematic diagram of the overall structure of an in-plane memristor , and FIG. 7(b) is a physical diagram of an in-plane memristor;

FIG. 8 is a performance diagram of an in-plane memristor in Embodiment4 according to the present disclosure; wherein FIG. 8(a) is an I-V hysteresis curve diagram, and FIG. 8(b) is an asymmetric current switching diagram;

FIG. 9 is a structure and performance test diagram of a piezoelectric device in Embodiment 4 according to the present disclosure; wherein FIG. 9(a) is a structural schematic diagram of the piezoelectric device, and FIG. 9(b) is a piezoelectric performance diagram of the piezoelectric device.

### DETAILED DESCRIPTION OF THE EMBODIMENTS

The following clearly and completely describes the technical solutions in embodiments of the present disclosure with reference to the drawings of embodiments of the present disclosure. Apparently, the described embodiments are only some but not all of the embodiments of the present disclosure. All other embodiments obtained by those of ordinary skill in the art based on the embodiments of the present disclosure without involving any creative effort shall fall within the scope of protection of the present disclosure.

In order to make the aforementioned objectives, features, and advantages of the present disclosure more readily obvious and understandable, the following is a further detailed description of the present disclosure with reference to the accompanying drawings and embodiments.

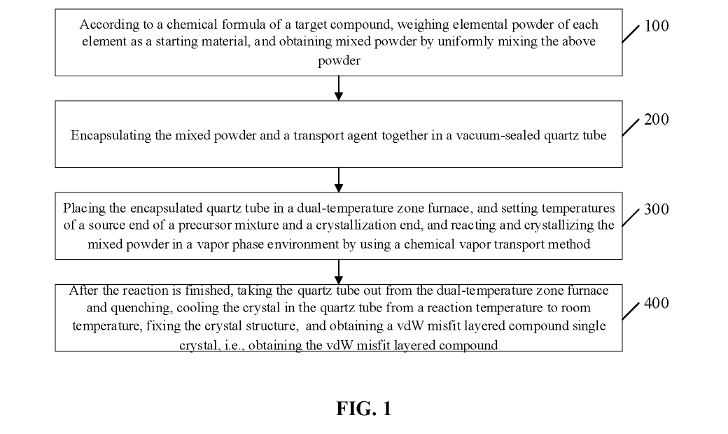

As shown in FIG. 1, the present disclosure provides a method for a vdW misfit layered compound based on solid-state high-temperature synthesis, including the following steps:

Step 100: according to the chemical formula of the target compound, the elemental powder of each element is weighed as the starting material, and the mixed powder is obtained by uniformly mixing the above powder;

Step 200: the mixed powder and the transport agent are encapsulated together in the vacuum-sealed quartz tube;

Step 300: the encapsulated quartz tube is placed in the dual-temperature zone furnace, and the temperatures of the source end of the precursor mixture and the crystallization end are set, and the mixed powder is reacted and crystallized in the vapor phase environment by using the chemical vapor transport method; and

Step 400: after the reaction is finished, the quartz tube is taken out from the dual-temperature zone furnace and quenched. The crystal in the quartz tube is cooled from the reaction temperature to the room temperature, the crystal structure is fixed, and the vdW misfit layered compound single crystal is obtained, i.e., the vdW misfit layered compound is obtained.

In the above step, the transport agent is a stannous halide compound, and one of stannous chloride and stannous bromide is selected as the stannous halide compound. The temperature range of the source end of the precursor mixture is 800-900 °C; the temperature range of the crystallization end is 750-850 °C, and the crystallization is performed by the chemical vapor transport method, with a growth time of 7-14 days.

The obtained vdW misfit layered compound is prepared by a solid-state high-temperature synthesis method, and is composed of at least two vdW material sublayers, where the first layer of the vdW material sublayer is a compound layer containing group IV or group V transition metals, and the second layer of the vdW material sublayer is a compound layer containing tin, lead, bismuth, antimony or rare earth metal elements, and atoms of the two vdW material sublayers are connected by the vdW force. The two vdW materials sublayers are a tetragonal phase layer A and a hexagonal phase layer B, respectively, and heterogeneous superlattices are formed based on stacking modes of ABAB and AAB. The crystal structure of the vdW misfit layered compound is characterized by the Raman spectroscopy and the STEM-HAADF, containing two distinct 2D components with different lattice constants, and exhibiting a staggered arrangement to form a misfit layered structure.

Furthermore, the general chemical formula of the vdW misfit layered compound is ([MX] _{1+δ})ₘ(TX₂)ₙ; where M is defined as one element selected from the tin, lead, bismuth, antimony or rare earth metal elements, T is defined as a group IV or group V transition metal element, X is defined as a sulfur element or a selenium element, the parameter δ is defined as an in-plane area ratio of two components, m is a stoichiometric number of an MX layer, and n is a stoichiometric number of a TX₂ layer.

According to the foregoing, the vdW misfit layered compound is applied in various functional devices based on its electrical properties, specifically including: lateral ferroelectric metal memristors, vertical piezoelectric devices, and superconducting ferroelectric memristor devices.

The hysteresis current-voltage hysteresis curve of the in-plane memristor of the vdW misfit layered compound has characteristics of low threshold voltage, and is further applied to the lateral ferroelectric metal memristor with low energy consumption. The crystal structure of the vdW misfit layered compound has a special crystal structure. Specifically, the crystal structure exhibits an out-of-plane symmetry breaking due to the mismatch of the lattice of the two sublayers, which deforms along the direction of the electric field under the action of the electric field and is applied to vertical piezoelectrics with efficient electromechanical conversion performance. VdW misfit layered compounds are Ising superconductors, which have the characteristics of a high upper critical field, and maintain a stable superconducting state in a strong magnetic field environment, so they are applied to superconducting ferroelectric memristive devices with high stability. The crystal structure of the vdW misfit layered compound exhibits an out-of-plane symmetry breaking due to the mismatch between two groups of sublayer lattices, which is deformed along the direction of the electric field under the action of the electric field, and is applied to the vertical piezoelectric device with high-efficiency electromechanical conversion performance. The vdW misfit layered compound is an Ising superconductor, exhibits a high upper critical field, and further maintains a stable superconducting state under a strong magnetic field environment, and is applied to a superconducting ferroelectric memristive device with high stability.

The following will further verify the above content by enumerating specific embodiments.

### Embodiment 1

In this embodiment, the preparation of the vdW misfit layered compound (SnSe)_{1.16}(NbSe₂) includes the following steps:

(1) Tin (Sn, with a purity of 99.99%), niobium (Nb, with a purity of 99.99%) and selenium (Se, with a purity of 99.99%) powder is weighed as starting materials, and uniformly mixed the powder in a ratio of 1.16:1:3.16 to obtain the mixed powder, and the mass of the mixed powder is about 1.5 g.

(2) 150 mg of stannous chloride (SnCl₂, with a purity of 99.99%) is used as a transport agent, and the mixed powder and the transport agent are encapsulated together in the vacuum-sealed quartz tube.

(3) The encapsulated quartz tube is placed in the dual-temperature zone furnace, the temperature of the source end of the precursor mixture is set to 900 °C, and the temperature of the crystallization end is set to 850 °C, and the mixed powder grows for 7 days by chemical vapor transport method, so that the mixed powder reacts and crystallizes in the vapor phase environment.

(4) After the reaction is finished, the quartz tube is taken out from the dual-temperature zone furnace and quenched, the crystal in the quartz tube is cooled from the reaction temperature to the room temperature, and the crystal structure is fixed, thereby obtaining a bright black sheet-like vdW misfit layered compound (SnSe)_{1.16}(NbSe₂) single crystal with millimeter size.

The vdW misfit layered compound (SnSe)_{1.16}(NbSe₂) obtained in embodiment 1 is tested and characterized as follows:

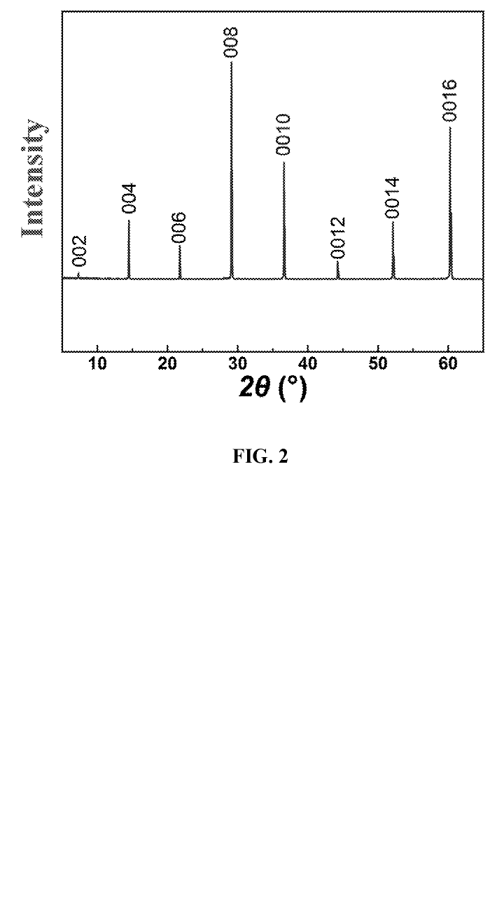

XRD is used to characterize the crystal structure of the material obtained in Embodiment 1, and the obtained results are shown in FIG. 2. The XRD pattern shows that all diffractions are (00l) peaks with diffraction angles ranging from 5 to 65 °, with a commensurate (002) peak and a small width at half height, indicating the grown (SnSe)_{1.16}(NbSe₂) single crystal sample exhibits high quality and good crystallinity.

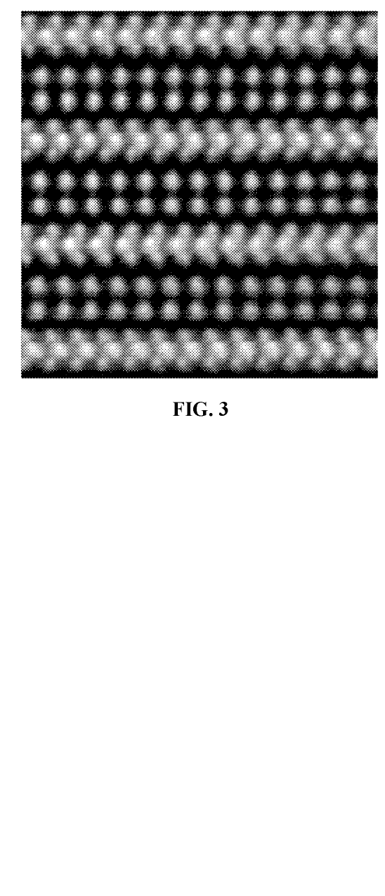

STEM-HAADF is used to characterize the crystal structure of the material obtained in Embodiment 1, and the obtained results are shown in FIG. 3. Through the STEM-HAADF images, the microscopic crystal structure of this vdW misfit superlattice (SnSe) _{1.16}NbSe₂ can be clearly observed, the local atomic structure shows alternately stacked SnSe and NbSe₂ heterolayers and two planar distinct features, and the high contrast produced by heavy atoms (such as Nb) provides detailed atomic arrangement information, showing the regular arrangement and distribution of layers of different materials. A wide range is also a highly ordered alternating heterogeneous superlattice stacking arrangement, indicating that it has long-period order.

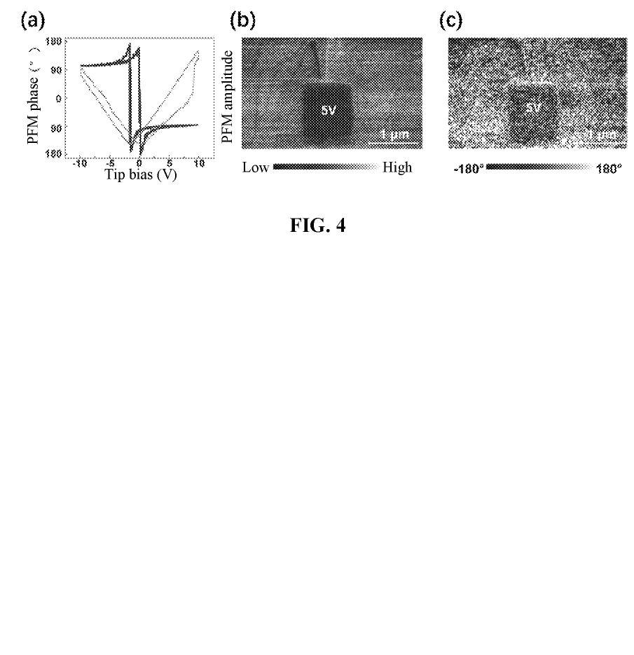

The ferroelectricity of the material obtained in Embodiment 1 is characterized by the LPFM, and the obtained results are shown in FIG. 4. At a resonant frequency of 750 kHz, FIG. 4(a) shows that the local electrically SS-PFM shows an amplitude butterfly curve and a phase cycle curve with a phase difference of 180 ° in the voltage range of -6 V to 6 V, indicating that the material obtained in Embodiment 1 exhibits hysteresis behavior of in-plane ferroelectric switching. This confirms that an electrically switchable bistable antiparallel polarization state exists in (SnSe)_{1.16}(NbSe₂), with polarization switching voltages of approximately -0.7 V and +0.6 V. FIG. 4(b) and FIG. 4(c) show the in-plane phase diagram of a square-loop pattern and amplitude domain diagram of the material obtained from Embodiment 1 after tip bias polarization of +5 V and -5 V, respectively, exhibiting antiparallel remanent polarization with a phase contrast of nearly 180 °. LPFM techniques have shown that (SnSe)_{1.16}(NbSe₂) exhibits in-plane ferroelectricity, providing the basis for its potential application in lateral ferroelectric metal memristor devices.

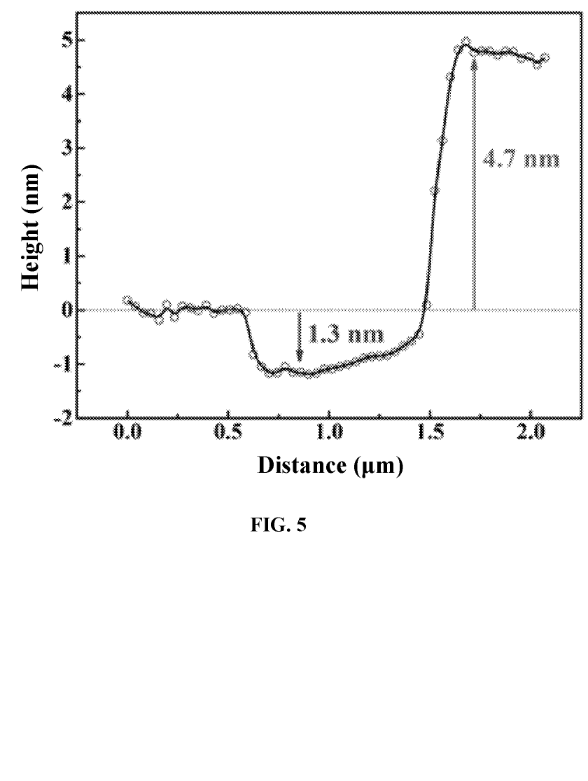

The piezoelectric effect of the material obtained in Embodiment 1 is characterized by the VPFM, and the obtained results are shown in FIG. 5. A decrease in the surface height of the (SnSe)_{1.16}(NbSe₂) crystal is observed by applying a voltage of -5 V to the 3×3 μm² region, and then an increase in the surface height of the crystal is observed by applying a voltage of +5 V to the central 1×1 μm² region. In the electrostriction region, its height decreased by 1.3 nm compared with the intrinsic region, while the height of the electrostriction high region increased by 4.7 nm compared with the intrinsic region. VPFM shows that (SnSe)_{1.16}(NbSe₂) has a piezoelectric effect, providing the basis for its potential application in vertical piezoelectric devices.

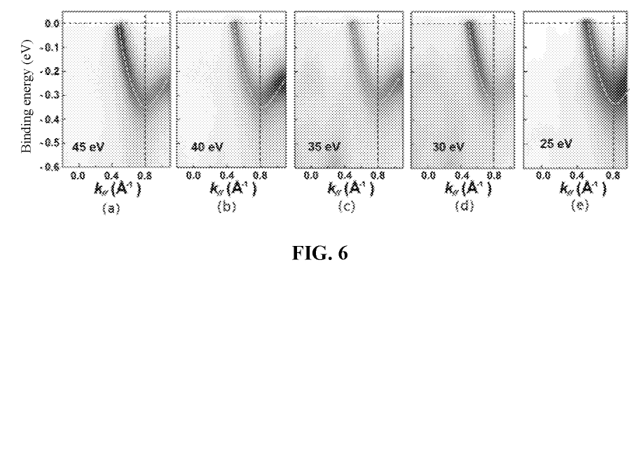

The electronic structure of the material obtained in Embodiment 1 is characterized by the ARPES, and the obtained results are shown in FIG. 6. Referring to FIG. 6(e), FIG. 6(d), FIG. 6(c), FIG. 6(b) and FIG. 6(a), the band dispersion along the Γ-M direction remains substantially unchanged when the photon energy varies from 25 eV to 45 eV, indicating that (SnSe)_{1.16}(NbSe₂) has quasi-two-dimensional electronic properties.

### Embodiment 2

In this embodiment, the preparation of the vdW misfit layered compound (SnSe)_{1.16}(NbSe₂)₂ includes the following steps:

(1) Tin (Sn, with a purity of 99.99%), niobium (Nb, with a purity of 99.99%) and selenium (Se, with a purity of 99.99%) powder is weighed as starting materials, and uniformly mixed the powder in a ratio of 1.16:2:5.16 to obtain the mixed powder, and the mass of the mixed powder is about 1.6 g.

(2) 200 mg of stannous bromide (SnBr₂, with a purity of 99.99%) is used as a transport agent, and the mixed powder and the transport agent are encapsulated together in the vacuum-sealed quartz tube.

(3) The encapsulated quartz tube is placed in the dual-temperature zone furnace, the temperature of the source end of the precursor mixture is set to 900 °C, and the temperature of the crystallization end is set to 850 °C, and the mixed powder grows for 7 days by chemical vapor transport method, so that the mixed powder reacts and crystallizes in the vapor phase environment.

(4) After the reaction is finished, the quartz tube is taken out from the dual-temperature zone furnace and quenched, the crystal in the quartz tube is cooled from the reaction temperature to the room temperature, and the crystal structure is fixed, thereby obtaining a vdW misfit layered compound (SnSe)_{1.16}(NbSe₂)₂ single crystal with a size of 2 mm and a thickness of 0.04-0.1 mm.

### Embodiment 3

In this embodiment, the preparation of the vdW misfit layered compound (SnSe)_{1.17}(NbSe₂) includes the following steps:

(1) Tin (Sn, with a purity of 99.99%), niobium (Nb, with a purity of 99.99%) and sulfur (S, with a purity of 99.99%) powder is weighed as starting materials, and uniformly mixed the powder in a ratio of 1.17:2:3.17 to obtain the mixed powder, and the mass of the mixed powder is about 1.6 g.

(2) 200 mg of stannous chloride (SnCl₂, with a purity of 99.99%) is used as a transport agent, and the mixed powder and the transport agent are encapsulated together in the vacuum-sealed quartz tube.

(3) The encapsulated quartz tube is placed in the dual-temperature zone furnace, the temperature of the source end of the precursor mixture is set to 850 °C, and the temperature of the crystallization end is set to 770 °C, and the mixed powder grows for 14 days by chemical vapor transport method, so that the mixed powder reacts and crystallizes in the vapor phase environment.

(4) After the reaction is finished, the quartz tube is taken out from the dual-temperature zone furnace and quenched, the crystal in the quartz tube is cooled from the reaction temperature to the room temperature, and the crystal structure is fixed, thereby obtaining a vdW misfit layered compound (SnSe)_{1.17}(NbSe₂) single crystal with a size of 5 mm.

### Embodiment 4

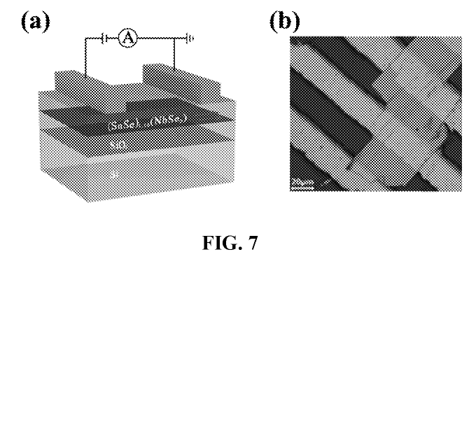

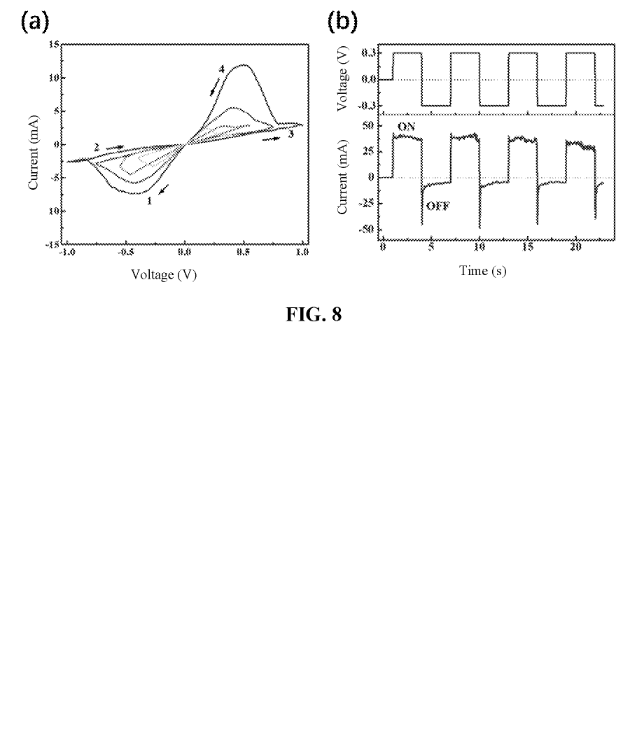

As shown in FIG. 7(a) and FIG. 7(b), the vdW misfit layered compound (SnSe)_{1.16}(NbSe₂) obtained in Embodiment 1 is prepared into an in-plane memristor. With reference to FIG. 8(a), the I-V hysteresis curve diagram is obtained by scanning under different bias voltages, visually presenting the voltammetric characteristics of the memristor. As shown in FIG. 8(b), asymmetric current switching is measured at ±0.3 V bias, showing repeatable reversible behavior between ON and OFF states. This supports effective polarization direction control via small drive voltages, indicating the (SnSe)_{1.16}(NbSe₂) ferroelectric metal memristor has the advantage of low power consumption.

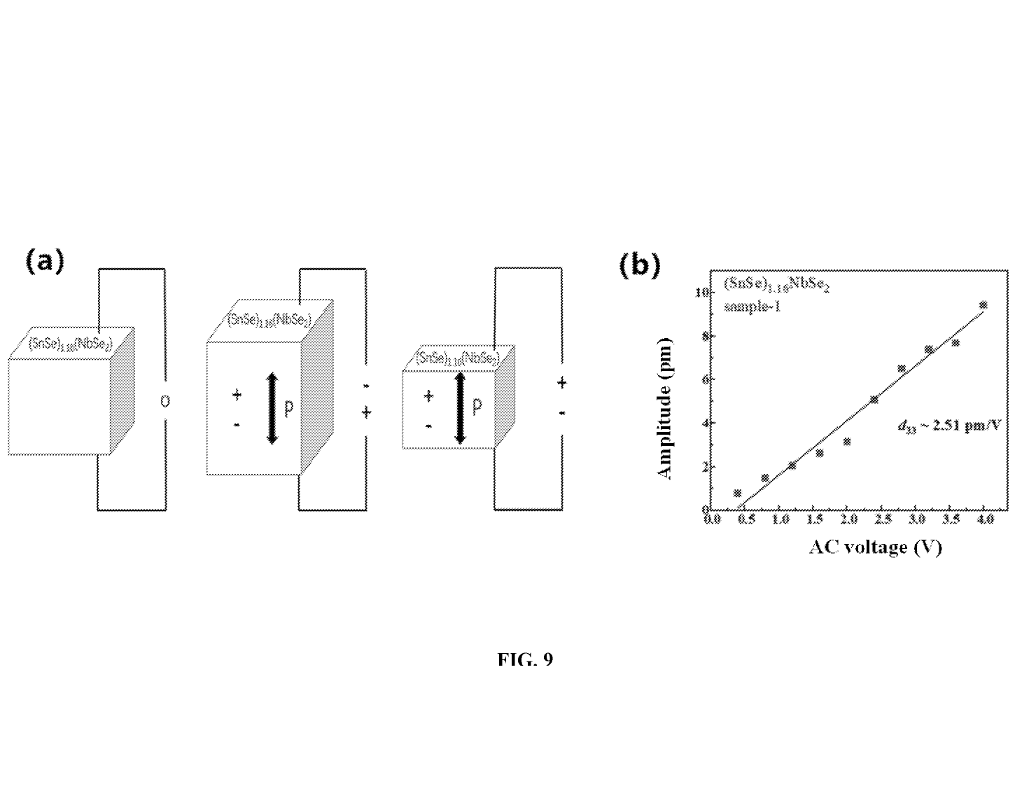

With reference to FIG. 9(a), the vdW misfit layered compound (SnSe)_{1.16}(NbSe₂) obtained in Embodiment 1 is fabricated into a piezoelectric device. When the applied electric field is opposite to the intrinsic polarization field of the piezoelectric material, the material of the piezoelectric device is stretched. When the applied electric field is parallel to the intrinsic polarization field of the piezoelectric material, the material of the piezoelectric device is compressed. As shown in FIG. 9(b), when an alternating current of varying amplitude is applied, the piezoelectric amplitude of the device increases linearly with the amplitude of the alternating current.

In view of the foregoing, the aforementioned method and application for synthesizing vdW misfit layered compound based on solid state high temperature, which addresses the problems of complex process, low efficiency and high cost of conventional preparation of vdW misfit layered compounds, constructs a functional device application regulation system, achieves its wide application in various fields, and provides a novel direction for the future development of science and technology.

The embodiments in this specification are described in a progressive manner. Each embodiment primarily highlights the differences from other embodiments, and each embodiment refers to the other embodiments for identical or similar aspects.

Specific examples have been used in the present disclosure to illustrate the principles and embodiments of the present disclosure. The above embodiments are provided solely to facilitate understanding of the methods and core concepts of the present disclosure. Furthermore, those skilled in the art may make modifications to the specific embodiments and scope of application based on the principles of the present disclosure. In summary, the content of this specification should not be taken as limiting the scope of the present disclosure.

What is claimed is:

1. A van der Waal's (vdW) misfit layered compound based on solid-state high-temperature synthesis, wherein the vdW misfit layered compound is prepared by a solid-state high-temperature synthesis method and consists of at least two vdW material sublayers, wherein a first layer of a vdW material sublayer is a compound layer containing group IV or group V transition metals, and a second layer of a vdW material sublayer is a compound layer containing tin, lead, bismuth, antimony or rare earth metal elements, and atoms of the two vdW material sublayers are connected by vdW force to form a vdW misfit layered compound with a chemical formula of (SnSe)_{1.16}(NbSe₂);
wherein the two vdW materials sublayers are a tetragonal phase layer A and a hexagonal phase layer B, respectively, and heterogeneous superlattices are formed based on stacking modes of ABAB and AAB; wherein a crystal structure of the vdW misfit layered compound is characterized by a Raman spectroscopy and an STEM-HAADF, containing two distinct 2D components with different lattice constants, and exhibiting a staggered arrangement to form a misfit layered structure.

2. A method of making the vdW misfit layered compound based on the solid-state high-temperature synthesis according to claim 1, wherein the solid-state high-temperature synthesis method comprises the following steps:
according to a chemical formula of a target compound, weighing elemental powder of each element as a starting material, and obtaining mixed powder by uniformly mixing the above powder;
encapsulating the mixed powder and a transport agent together in a vacuum-sealed quartz tube; wherein the transport agent is a stannous halide compound, and one of stannous chloride and stannous bromide is selected as the stannous halide compound;
placing the encapsulated quartz tube in a dual-temperature zone furnace, and setting temperatures of a source end of a precursor mixture and a crystallization end, and reacting and crystallizing the mixed powder in a vapor phase environment by using a chemical vapor transport method; wherein a temperature range of the source end of the precursor mixture source is 800-900 °C; the temperature range of the crystallization end is 750-850 °C; and the crystallization is performed by the chemical vapor transport method, with a growth time of 7-14 days; and
after the reaction is finished, taking the quartz tube out from the dual-temperature zone furnace and quenching, cooling the crystal in the quartz tube from a reaction temperature to room temperature, fixing the crystal structure, and obtaining a vdW misfit layered compound single crystal as the vdW misfit layered compound.

3. A method of using the vdW misfit layered compound based on the solid-state high-temperature synthesis according to claim 1, comprising incorporating the vdW misfit layered compound in functional devices based on its electrical properties, wherein the devices are selected from: a lateral ferroelectric metal memristor, a vertical piezoelectric device, and a superconducting ferroelectric memristor device.

4. The method of using the vdW misfit layered compound based on the solid-state high-temperature synthesis according to claim 3, wherein a hysteresis current-voltage hysteresis curve of an in-plane memristor of the vdW misfit layered compound has characteristics of low threshold voltage, and is further applied to the lateral ferroelectric metal memristor with low energy consumption.

5. The method of using the vdW misfit layered compound based on the solid-state high-temperature synthesis according to claim 3, wherein a crystal structure of the vdW misfit layered compound exhibits an out-of-plane symmetry breaking due to a mismatch between two groups of sublayer lattices, is deformed along a direction of an electric field under an action of the electric field, and is applied to the vertical piezoelectric device with high-efficiency electromechanical conversion performance.

6. The method of using the vdW misfit layered compound based on the solid-state high-temperature synthesis according to claim 3, wherein the vdW misfit layered compound is an Ising superconductor, exhibits a high upper critical field, further maintains a stable superconducting state under a strong magnetic field environment, and is applied to a superconducting ferroelectric memristive device with high stability.
